(19) United States
(12) Patent Application Publication
(10) Pub. No.: US 2004/0183144 A1
(43) Pub. Date: Sep. 23, 2004

(54) Plasma nitridization for adjusting transistor threshold voltage

(76) Inventors: Kevin L. Beaman, Boise, ID (US); John T. Moore, Boise, ID (US); Ronald A. Weimer, Boise, ID (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/393,718

(22) Filed: Mar. 20, 2003

(51) Int. Cl. H01L 29/76

(52) U.S. Cl. 257/411

(57) ABSTRACT

A method of adjusting the threshold voltage of semiconductor devices by incorporating nitride into the isolation layer so as to decrease the mobility of charge carriers and thereby increase the threshold voltage required to activate the device. The nitrogen incorporation method may comprise of decoupled plasma nitridization (DPN) and the DPN can be performed in-situ during gate oxide formation. The amount of threshold voltage can be varied by adjusting the DPN treatment time and processing parameters.

### BACKGROUND OF THE INVENTION

1. Field of the Invention

This invention relates to integrated circuit processing and, more particularly, to a method of adjusting the threshold voltage of transistors using a nitridization process.

2. Description of the Related Art

The transistor of an integrated circuit typically comprises a source, a drain, and a gate structure that is formed on a substrate surface above the source and the drain. Furthermore, the transistor can be activated by applying a voltage to the gate which in turn creates a conductive channel between the source and the drain in the substrate. When a voltage is applied to the gate through the gate metal, a field effect takes place in the surface of the semiconductor. The effect is either a buildup of charge or a depletion of charges in the wafer surface under the top plate. Which event occurs depends on the doping conductivity type in the wafer under the gate and the polarity of the gate voltage. The buildup or depletion of charge creates a channel under the gate which connects the source and the drain.

The conductive channel permits current to travel from the source to the drain. Furthermore, it is well understood that the source, drain, and channel regions of a transistor can be formed by doping selected areas of the substrate using techniques well known in the art. In particular, a channel region that is implanted with an N-type dopant such as phosphorous or arsenic atoms typically becomes part of what is generally know as N-channel access transistors. Likewise, channel regions implanted with P-type dopants such as boron are commonly used as part of P-channel access transistors.

Furthermore, it is generally known that the voltage applied to the gate structure has to exceed a minimum voltage in order to create a conductive channel in the substrate between the source and the drain. This minimum voltage, otherwise known as the threshold voltage (Vt), can be affected by a variety of factors such as device dimension and substrate purity. In particular, impurities in the substrate have shown to increase the threshold voltage, while reduced device dimensions are known to decrease the threshold voltage. Devices with a low threshold voltage are generally undesirable as they are susceptible to activation by stray currents and other electrical noise. In particular, transistors having an excessively low threshold voltage are known to be less reliable as they can be inadvertently activated by weak currents emanating from other devices. On the other hand, transistors with an exceedingly high threshold voltage are also undesirable as a stronger power supply is typically required to effectively operate such devices.

To address this problem associated with the threshold voltage of transistors, an ion implantation process is commonly used to adjust the threshold voltage of a transistor to a desired level. In particular, the ion implantation process typically involves doping the substrate with a predetermined amount of ions using a commonly known implantation process. In some cases the added impurity can increase the threshold voltage of the transistor and the amount of increase in voltage can be tuned by varying the amount of dopant. For instance, an implant of boron atoms into the P-type substrate of an N-channel access transistor will make the threshold voltage more positive with increased dosage. Furthermore, silicon and germanium atoms implanted into the substrate have also been effective in adjusting the voltage of N-channel transistors. As such, various ion implantation processes have been developed to adjust the threshold voltage of transistors in most integrated circuits.

Disadvantageously, however, the ion implantation process is typically expensive and time consuming. The wafer must be positioned in an ion implantation system wherein ions can be directed towards exposed regions of the wafer to thereby implant the ions in the wafer. The ion implantation process often results in damage to the crystalline structure of the wafer which can result in leakage currents. In particular, the ion implantation process entails doping the substrate in a manner that is likely to result in increased current leakage in the P—N junction between the source and the channel region. Furthermore, such current leakage is known to undesirably affect the performance of a memory circuit as it vitiates the charge carrying capacity of the cell which in turn unfavorably increases the number of refresh times necessary. Moreover, as device dimensions decrease, it becomes increasingly more difficult to ensure that ions are implanted at the appropriate position within the substrate to obtain the desired effect on threshold voltage. Hence, the cost associated with ion implantation to affect the increased difficulty in controlling threshold voltage with ion implantation indicates that there is a continuing need for other mechanisms for controlling the threshold voltage of a semiconductor device.

Hence, from the foregoing, it will be appreciated that there is a need for a cost effective and convenient method of adjusting the threshold voltage of transistors. To this end, there is a particular need for a less expensive method of adjusting the threshold voltage of a transistor without causing current leakage across the device.

### SUMMARY OF THE INVENTION

The aforementioned needs are satisfied by the method of the present invention which uses a nitridization process to adjust the threshold voltage of a semiconductor device.

In one aspect, the invention comprises a method of adjusting the voltage of a semiconductor device needed to create a field effect depletion region in a semiconductor substrate of the semiconductor device. The method comprises forming an isolation layer on a first surface of a semiconductor substrate and forming a gate on the isolation layer so that the application of a voltage to the gate results in the creation of a depletion region in the region of the semiconductor substrate located adjacent the isolation layer. In one embodiment, the method further comprises treating the isolation region with nitrogen wherein the nitrogen inhibits the mobility of charge carriers in the isolation region, which in turn increases the threshold voltage that must be applied to the gate. Preferably, the nitrogen is incorporated into the isolation region using a decoupled plasma nitridization (DPN) process. Furthermore, the isolation region may be a gate oxide layer comprised of a silicon dioxide, nitride, tantalum-based, or BST material. Furthermore, the invention can be used to adjust the voltage of a variety of semiconductor devices including dual-gate transistors, p-channel transistors, and n-channel transistors.

In another aspect, this invention comprises a method of inhibiting mobility of charge carriers in an isolation layer of a semiconductor device. The method comprises forming the isolation layer in a semiconductor substrate and incorporating nitrogen into the isolation layer. In one embodiment, the step of incorporating nitrogen into the isolation layer comprises depositing between about 10 to 25% of nitrogen within the isolation layer. In another embodiment, the step of incorporating nitrogen into the isolation layer comprises providing the isolation layer with a concentration of nitrogen that is between about 10 to 25%. Preferably, the isolation layer comprises an oxide layer made of a material such as SiO₂ wherein nitrogen is incorporated into the oxide layer while the oxide layer is being formed. Preferably, the step of incorporating nitrogen into the isolation layer comprises exposing the oxide layer to an energetic nitrogen environment and forming a layer of nitride on the upper surface of the gate oxide. Moreover, the nitrogen incorporated into the oxide layer preferably corrects structural defects present in the oxide layer, wherein the structural defects comprises atomic vacancies present in the oxide layer. The nitrogen atoms fill the atomic vacancies present in the oxide structure and substantially reduce the charge that has developed in the oxide layer as a result of these atomic vacancies.

In yet another aspect, the invention comprises a method of adjusting the threshold voltage required to activate a semiconductor device wherein the method comprises forming an isolation layer on a semiconductor substrate and incorporating nitrogen to the isolation layer so as to inhibit the charge carrier mobility in the isolation layer so that a higher threshold voltage is required to activate the semiconductor device. The method further comprises forming a gate on the isolation layer so that application of the higher threshold voltage to the gate results in the activation of the semiconductor device. Preferably, a plasma nitridization (PN) process such as a decoupled plasma nitridization (DPN) process provides a source of nitrogen to be deposited on the isolation layer and the isolation layer is generally comprised of a gate oxide material. In one embodiment, the nitridization process can be performed in-situ during gate oxide formation, gate conditioning, or gate dielectric deposition.

In yet another aspect, the invention comprises a method of adjusting the threshold voltage of a transistor gate. The method comprises forming a gate oxide layer on a semiconductor substrate and determining the amount of nitrogen that must be incorporated in the gate oxide layer to inhibit the mobility of charge carriers to thereby achieve a desired degree of threshold voltage adjustment. The method further comprises incorporating the required amount of nitrogen to the gate oxide layer so as to adjust the threshold voltage that must be applied and forming a gate on the gate oxide layer so the application of the threshold voltage to the gate results in the creation of a depletion region in the region of the semiconductor substrate located adjacent the isolation layer. In one embodiment, incorporating the required amount of nitrogen into the gate oxide layer comprises exposing the gate oxide to a PN treatment for a predetermined length of time wherein a longer PN treatment time or higher PN power results in a higher increase in threshold voltage. In another embodiment, forming the gate comprises forming a polysilicon layer on an upper surface of the gate oxide layer, forming a metal or silicide layer on an upper surface of the polysilicon layer, and forming a nitride cap on an upper surface of the metal or silicide layer.

In yet another aspect, the preferred embodiments to the present invention provide a semiconductor device comprising a semiconductor substrate, an isolation layer formed on a first surface of the substrate, wherein nitrogen is incorporated into the isolation layer to inhibit mobility of charge carriers in the isolation layer. The device further comprises a gate structure formed on a first surface of the isolation layer, wherein application of a threshold voltage to the gate structure results in the creation of a depletion region in the region of the semiconductor substrate located adjacent the isolation layer. In one embodiment, the device has a threshold voltage of between about 0.1 to 3 volts. In another embodiment, the device can be a transistor or a dual-gate transistor.

Advantageously, the present invention provides a cost-effective and convenient method of adjusting the voltage of a semiconductor device. Unlike the ion-implantation processes conventionally used to adjust threshold voltage, the nitridization method of the present invention does not involve multiple ion implantation steps and can be conveniently performed using existing equipment and processes in a semiconductor fabrication line. Furthermore, the present method will not cause damages to the crystalline structure of the wafer whereas the traditional processes for threshold voltage adjustment are known to result in crystalline defects which in turn increase current leakage in the P—N junction between the source and the channel region. Furthermore, the present method can be used to conveniently tune the threshold voltage to a desired level without varying the amount of impurities implanted in the semiconductor substrate. These and other objects and advantages of the present invention will become more fully apparent from the following description taken in conjunction with the accompanying drawings.

### BRIEF DESCRIPTION OF THE DRAWINGS

FIG. 1 is a schematic illustration of a process flow of one preferred embodiment of the present invention, using a nitridization process to adjust the threshold voltage of a semiconductor device;

FIG. 2 is a schematic illustration of a process flow of another preferred embodiment of the present invention, wherein the nitridization process is formed during gate stack formation;

FIG. 3 is a sectional view of a partially formed MOSFET device illustrating the formation of an isolation layer;

FIG. 4 is a schematic sectional view of a partially formed MOSFET device of FIG. 3 illustrating an incorporation of nitrogen to the isolation layer;

FIG. 5 is a schematic sectional view of a partially formed MOSFET device of FIG. 4 illustrating the formation of a gate;

FIG. 6 is a schematic sectional view of a partially formed MOSFET device of FIG. 5 illustrating the formation of source, drain, and channel regions;

FIG. 7 is a schematic view of a partially formed MOSFET device illustrating a dual-gate transistor having nitridized isolation layers;

FIG. 8 is a graph illustrating the relationship between DPN treatment time and the shift in the threshold voltage of a semiconductor device.

### DETAILED DESCRIPTION OF THE PREFERRED EMBODIMENT

Reference will now be made to the drawings wherein like numerals refer to like parts throughout. As will be described herein below, the process of the preferred embodiments provides a method of adjusting the transistor threshold voltage by incorporating nitride to the gate oxide layer of the transistor so as to inhibit the mobility of charge carriers in the oxide and thereby increase the threshold voltage required to activate the transistor. As will also be described herein below, the method has also shown to improve gate hardening as well as raising the dielectric constant of the isolation layer, which allows the use of a thinner dielectric layer in semiconductor devices.

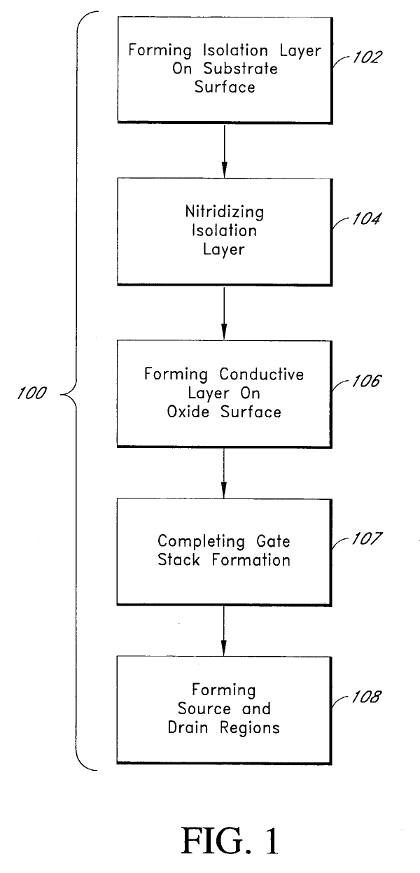

FIG. 1 schematically illustrates a process flow 100 of the preferred embodiment of adjusting the threshold voltage of a transistor using a plasma nitridization process. As shown in FIG. 1, the process begins with a first step 102 comprising the formation of an isolation layer onto a substrate surface. The substrate surface may comprise a single crystal wafer, such as an intrinsic or lightly doped silicon substrate or other semiconductive layer in which active or operable portions of the electrical devices are formed. As will be described in greater detail below, in this embodiment, the substrate surface is prepared for the formation of a field effect transistor which generally comprises a source, a drain, a conduction channel, and a gate structure. As will be described in further detail below, the isolation layer, otherwise known as the gate oxide, serves as a base for the gate structure and isolates the gate electrode from the substrate surface.

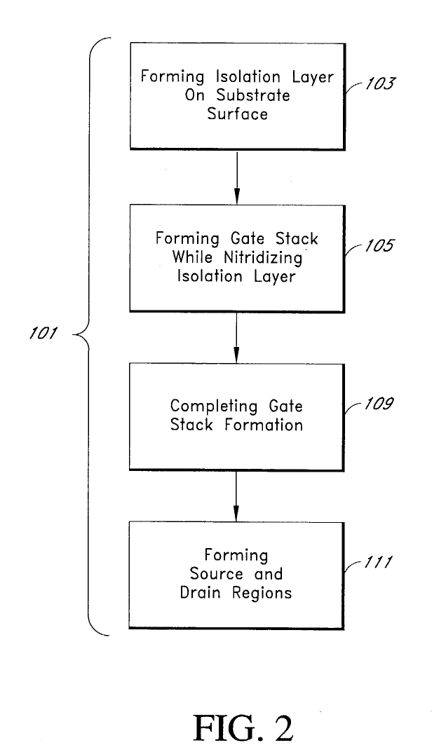

As it is also shown in FIG. 1, following the formation of the gate oxide, a second step 104 of the process 100 of the preferred embodiment comprises incorporating nitrogen into an upper surface of the gate oxide. Preferably, the nitrogen is incorporated using a Decoupled Plasma Nitridization (DPN) process. DPN is a process designed to incorporate a high concentration of nitrogen into the surface of a gate oxide. In contrast to Remote Plasma Nitridization (RPN) processes which typically use a remote microwave plasma source, the DPN process utilizes RF plasma that is struck in the same chamber as the wafer. As will be described in greater detail below, the DPN process exposes the oxide layer to an energetic nitrogen environment and forms a layer of nitride on the upper surface of the gate oxide. In another embodiment, the nitrogen-can be deposited in-situ by performing the DPN process during gate oxidation, gate conditioning, gate dielectric deposition. As shown in FIG. 2, the nitridization process is conducted during step 105 in which the gate stack is being formed. Nitridizing the oxide layer during gate formation reduces the number of manufacturing steps, which results in a more efficient process. In one embodiment, the nitrogen can be deposited using both the DPN process and a conventional doping process.

Advantageously, the nitride will seep into the underlying oxide layer and correct the structural defects present in the oxide layer. The nitrogen atoms will fill the atomic vacancies present in the oxide structure and thus substantially reduce the charge that has developed in the oxide layer as a result of these atomic vacancies. Generally, it is undesirable for the oxide layer to be charged as it can facilitate the flow of current from the gate structure to the underlying channel and thereby lower the threshold voltage of the device. Furthermore, the nitrogen can tie up the mobility of charge carriers in the oxide layer and thereby increase the threshold voltage required to activate the underlying channel region.

The DPN process parameters can be set in the following general ranges: plasma output power (100-3,000 Watts), pressure (5-50 millitorr), temperature (50-400 C), nitrogen flow (5-500 cc/min). In one embodiment, the DPN process parameters are set as follows: plasma output power (900 Watts), pressure (7 millitorr), temperature (75 C), nitrogen flow (200 cc/min). However, it can be appreciated that the processing parameters can be varied without departing from the spirit of the invention. Furthermore, it has been determined that the length of DPN processing time directly affects the amount of shift in threshold voltage. In one embodiment, the DPN treatment time is preferably set at 1 minute for adjusting the transistor threshold voltage from −0.500 to −0.625. In other embodiments, the treatment time can be optimized for the desired level of threshold voltage for a particular device. Preferably, the DPN process forms an N-gradient concentration within the oxide layer.

The longer the DPN treatment time, the more nitride is introduced to the oxide layer which is known to tie up more charge carriers. Consequently, the extension of the DPN treatment time will increase the amount of nitride incorporation into the gate oxide which further inhibits the mobility of charge carriers. As such, an increased restraint in the charge carrier mobility will make the threshold voltage more positive in a NMOS device and cause the threshold voltage to be more negative in a PMOS device. Particularly, it is generally known that activation of a NMOS device requires a rise in positive voltage and activation of a PMOS device requires an increase in negative voltage.

Advantageously, the present method of adjusting threshold voltage does not increase current leakage as it does not involve doping the substrate surface. Unlike the conventional threshold voltage adjustment method that comprises a series of ion implantation steps, the method of the preferred embodiment does not require doping of the substrate. In particular, doping of the substrate is generally known to increase current leakage and increase the refresh time in a memory circuit. The present method introduces a novel way of increasing the threshold voltage of a semiconductor device by inhibiting the mobility of charge carriers in the isolation layer so as to hinder the flow of current through the isolation layer.

As is also shown in FIG. 1, the process 100 comprises a third step 106 following the nitridization process. In the third step 106, a layer of conductive material is formed on an upper surface of the isolation layer. In one embodiment, the conductive layer comprises a polysilicon material that is commonly used in gate stack formation. Furthermore, it can be appreciated that additional layers can be formed on the conductive layer to complete the formation of a gate stack. It can also be appreciated that the present method is applicable to most gate stacks having a polysilicon base.

Subsequent to the formation of the layers comprising the gate stack, the substrate is etched to further define the contour of the gate stack in a fourth step 110. Following the completion of the gate stack, a fifth step 112 comprises the formation of a source and drain regions in the substrate. In particular, the source and drain regions are formed using well known methods in the art which generally involve doping the substrate in selected areas. In this embodiment, a well known N-type source and drain regions are formed by doping an area on the substrate with a phosphorous and arsenic dopant using methods that are well known in the art. In another embodiment, a well known P-type source and drain regions can be formed by doping an area on the substrate with boron using methods that are well known in the art. Following the formation of the source and drain regions, a known field effect transistor is typically created.

As will be described in greater detail below, the threshold voltage of the transistor can be increased so as to prevent stray currents from activating the device. In particular, the threshold voltage can be tuned by varying the processing time or plasma power of the DPN treatment. In contrast to the conventional threshold voltage adjustments, the preferred methods do not require repetitive doping of the substrate and therefore are unlikely to cause current leakage in the circuit. While one aspect of the preferred methods of the present invention is directed toward improving current leakage in a semiconductor device, it will be appreciated that the preferred methods can be used in conjunction with other techniques that may or may not improve current leakage in the semiconductor device.

FIG. 2 shows another preferred process 101 of the present invention in which nitrogen is incorporated into the oxide layer during gate formation. As shown in FIG. 2, the process 101 begins with step 103, which comprises forming an oxide layer on a substrate surface. The process 101 further includes a gate formation and nitridization process in step 105 during which nitrogen is incorporated into the oxide layer during gate formation. Preferably, nitrogen is incorporated using a DPN process. The method further comprises step 107 in which the gate formation/nitridization process is complete and step 109 in which the source and drain regions are formed. Advantageously, nitridizing the oxide layer during gate formation reduces the number of manufacturing processing steps and manpower.

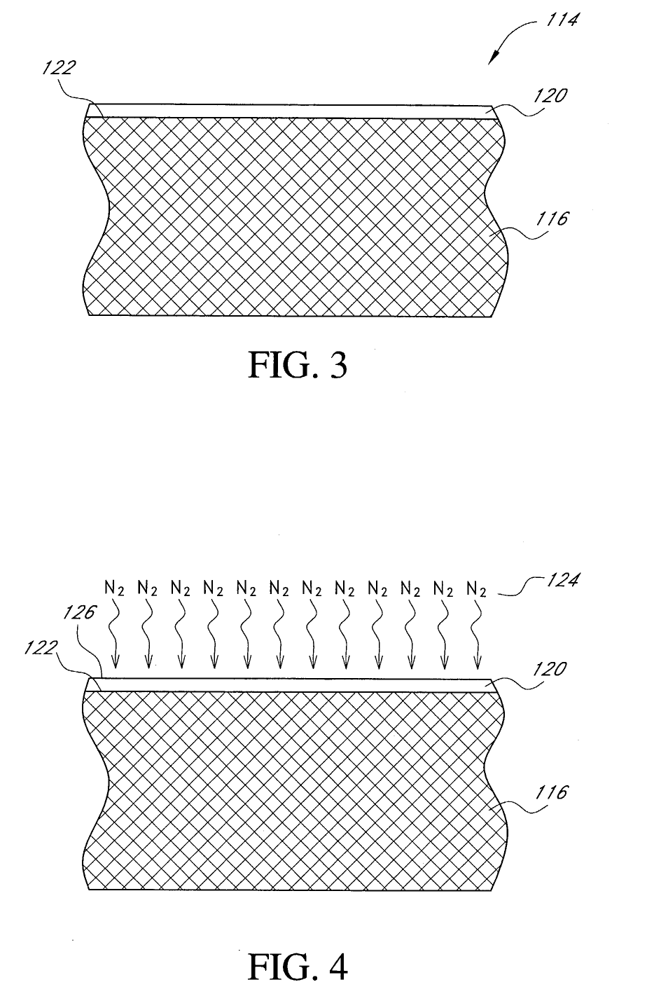

FIG. 3 illustrates a partially fabricated integrated circuit assembly 114 having a substrate 116 which may comprise a single crystal wafer, such as an intrinsic or lightly doped silicon substrate or other semiconductive layer in which active or operable portions of the electrical devices are formed. In particular, the substrate assembly 114 of the illustrated embodiment is prepared for the formation of a field effect transistor which generally comprises a source region, a drain region, a conduction channel, and a gate structure.

As FIG. 3 illustrates, a layer of gate oxide 120 is first formed on an upper surface 122 of the semiconductor substrate 116. In one embodiment, the gate oxide 120 comprises a silicon dioxide and is formed using well known gate oxide growth techniques, such as dry/wet/dry or dry only oxidation. However, it can be appreciated that there are other suitable insulating material that can be deposited using varying techniques without departing from the scope of the invention. As it is generally understood in the art, the gate oxide 120 will form a portion of the gate structure of a field effect transistor and is typically interposed between the conduction channel and the gate electrode.

In one embodiment, the gate oxide comprises a nitride material while in another embodiment, the gate oxide may be made of a tantalum based material. In yet another embodiment, the gate oxide may be comprised of a BST material or other advanced dielectric. Furthermore, the gate oxide 120 is generally known to have structural defects such as atomic vacancies scattered throughout the layer. These atomic vacancies tend to create a charge in the oxide layer. The charged oxide layer in turn facilitates the flow of current and therefore lower the threshold voltage.

As FIG. 4 illustrates, nitrogen 124 is subsequently incorporated onto an upper surface 126 of the gate oxide 120. Preferably, the nitrogen 124 is deposited using a decoupled plasma nitridization (DPN) process. Advantageously, the nitrogen 124 deposited on the upper surface 126 of the gate oxide 120 fills the atomic vacancies present in the oxide to thereby inhibit charge carrier mobility in the oxide and increase the amount of threshold voltage needed to activate the device. Furthermore, as described above, the magnitude of change in the threshold voltage is dependent on the amount of nitrogen incorporated into the oxide, which in turn depends on the DPN treatment time.

In contrast to the threshold voltage adjustment methods known in the art, the present invention provides a novel method that does not require a series of ion implantation steps or doping of the substrate. Advantageously, the present invention reduces the processing time that is typically required for an ion implantation process and also decreases the leakage across the source and drain junction. In the preferred embodiment, the DPN process is used to incorporate nitrogen to the gate oxide and the nitrogen can be incorporated in-situ by performing the DPN process during gate oxide formation.

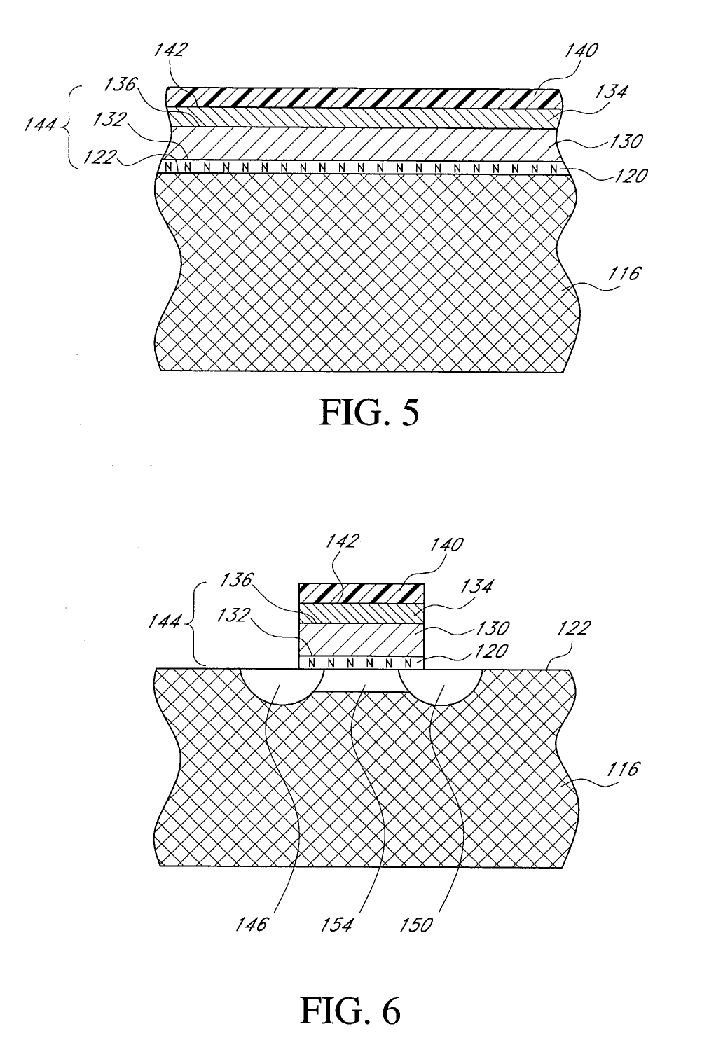

Following DPN treatment, a conductive layer 130 is formed in an upper surface 132 of the gate oxide layer 120 as shown in FIG. 5. In one embodiment, a conductive polysilicon layer is formed using well-known polysilicon deposition techniques such as LPCVD. As is also shown in FIG. 5, a metal layer 134 is formed on an upper surface 136 of the conductive polysilicon layer 130. In one embodiment, the metal layer 134 comprises tungsten silicide (WSix) and is deposited using a method well known in the art. Furthermore, as shown in FIG. 4, a cap layer 140 is formed on an upper surface 142 of the metal layer 134. Preferably, the cap layer 140 comprises a layer of nitride that is formed using a well known deposition method such as chemical vapor deposition (CVD). Furthermore, the cap layer 140 completes the formation of a gate stack 144 for the transistor of the preferred embodiment.

It will be appreciated that the various layers of material defining the gate stack 144 are formed of material having varying compositions and thickness depending upon the particular application. The exact configuration of the gate stack 144 will vary depending upon the particular circuit being formed. Furthermore, as described above, the method of using nitrogen to adjust threshold voltage can be accomplished with any of a number of variations in the gate stack 144.

With reference to FIG. 6, the gate stack 144 is further contoured using a well known print and etch operation. Subsequent to the formation of the gate stack 144, a source region 146 and a drain region 150 are formed in an active area of the semiconductor substrate 116 so as to be immediately adjacent the upper surface 122 of the substrate 116. The source region 146 and the drain region 150 are formed by selectively masking and then implanting or doping selectively exposed regions of the substrate 116 in a well-known manner so as to produce different doped regions that will comprise the source and drain regions 146, 150. As is illustrated in FIG. 5, the source and drain regions 146, 150 are positioned immediately adjacent the gate stack 144 such that the edge of the source and drain regions 146, 150 immediately adjacent the upper surface 122 is located substantially adjacent a doped region 154 of the silicon substrate 116.

As discussed above, the portion of the doped region 154 immediately adjacent the upper surface 122 and immediately adjacent the oxide layer 120 of the gate stack 144 is the region in which a channel will be created between the source region 146 and the drain region 150 upon an application of voltage to the gate stack 144. Preferably, application of a threshold voltage Vt to the gate stack 144 of the transistor produces a channel that extends between the source region 146 and the drain region 150 and allows conduction of charge carriers therebetween. Although the preferred embodiment illustrates a single gate transistor, it can be appreciated that the same process can be used to adjust threshold voltage for dual-gate transistors, and other semiconductor devices without departing from the scope of the invention.

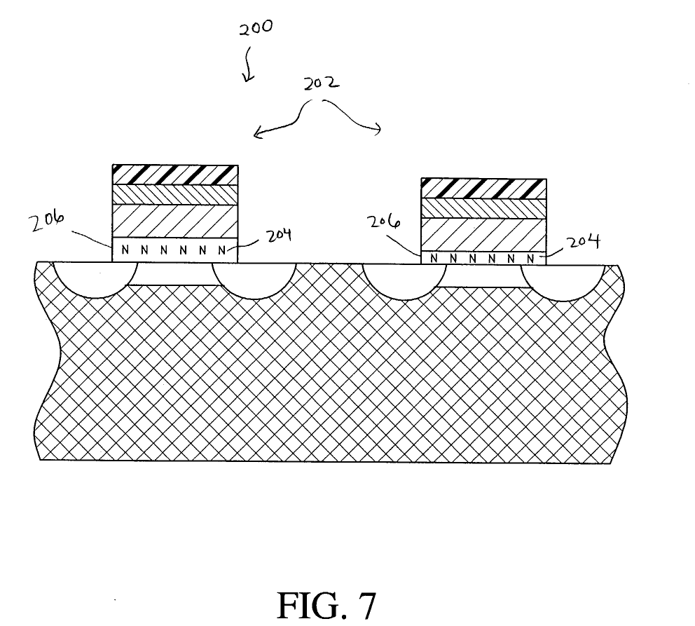

FIG. 7 provides a schematic illustration of another semiconductor device 200 in which the preferred process can be applied to adjust the threshold voltage, and/or improve gate hardening, and/or increase the dielectric constant. In one embodiment, the preferred methods improve transistor mobility by about 25% as compared to conventional gate hardening methods. As shown in FIG. 7, the semiconductor device 200 comprises a dual-gate transistor 202 wherein nitrogen 204 is incorporated into the oxide layer 206 of each gate stack to inhibit the mobility of charge carriers in the oxide layer 206. As described above, the nitrogen 204 can be incorporated using a DPN process or a combination of DPN and conventional doping process. The dual-gate transistor device 202 can include, but is not limited to, devices with two different transistors operating at different voltages having two different oxide thickness, devices in which the gate dielectric has electrodes on both sides, gate with two types of conductors, or devices with a floating and non-floating gate with insulation in between. Furthermore, it will be appreciated that the present invention also includes within its scope embodiments wherein the nitrogen layer is interposed between a first and a second oxide layer. In particular, the first oxide layer is formed on the substrate, followed by a nitridization process in which nitrogen is incorporated into the first oxide layer, and then followed by formation of the second oxide layer.

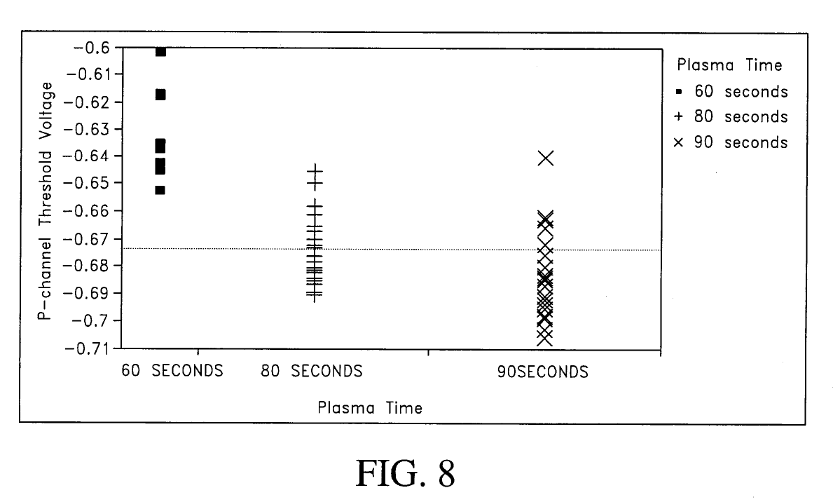

As shown in FIG. 8, experimental results indicate that the voltage threshold of a P-channel transistor shifts in the negative direction after nitridization. As FIG. 8 also illustrates, the amount of shift largely depends on the DPN treatment time. For instance, as DPN treatment time of the oxide increases, the V-T curve of the transistor shifts more toward the negative direction. As such, the DPN treatment time can be conveniently used to tune the threshold voltage of the transistor. Advantageously, the threshold voltage can be controlled by regulating the amount of nitrogen being incorporated into the gate oxide as demonstrated by FIG. 8.

In contrast to the traditional processes used to adjust threshold voltage, the present method can be implemented in a cost-efficient manner without subjecting the substrate to multiple implantation steps which is known to cause damages to the crystalline structure of the wafer. As such, the present threshold adjustment method will not increase current leakage in the P—N junction between the source and channel region. Advantageously, the preferred embodiments of the present invention provide a convenient method of tuning the threshold voltage to a desired level without creating structural defects in the semiconductor substrate. Moreover, the preferred embodiments also provide a technique that has shown to improve gate hardening, as well as raising the dielectric constant, thereby allowing the use of an electrically thinner dielectric. Although the preferred embodiments of the present invention have shown, described and pointed out the fundamental novel features of the invention, as applied to these embodiments, it will be understood that various omissions, substitutions and changes in the form of the detail of the device illustrated may be made by those skilled in the art without departing from the spirit of the present invention. Consequently, the scope of the invention should not be limited to the foregoing description, but should be defined by the appended claims.

What is claimed is:

1. A method of adjusting the voltage of a semiconductor device needed to create a field effect depletion region in a semiconductor substrate of the semiconductor device, the method comprising:
forming an isolation layer on a first surface of the semiconductor substrate;
forming a gate on the isolation layer so that the application of a threshold voltage to the gate results in the creation of a depletion region in the region of the semiconductor substrate located adjacent the isolation layer; and
treating the isolation layer so as to inhibit mobility of charge carriers in the isolation layer to thereby adjust the threshold voltage that must be applied to the gate so as to create the depletion region in the region of the semiconductor substrate located adjacent the isolation region.

2. The method of claim 1, wherein treating the isolation layer comprises incorporating nitrogen into the isolation layer.

3. The method of claim 2, wherein incorporating nitrogen into the isolation layer comprises exposing the isolation layer to a decoupled plasma nitridization (DPN) treatment.

4. The method of claim 3, wherein the DPN treatment comprises plasma output power between about 100-3,000 Watts, processing pressure between about 5-50 Millitorr, temperature between about 50-400 C, and nitrogen flow between about 5-500 cc/min.

5. The method of claim 1, wherein treating the isolation layer comprises treating the isolation layer so as to increase the threshold voltage of a dual-gate transistor.

6. The method of claim 4, wherein treating the isolation layer comprises treating the isolation layer so as to increase the magnitude of the negative voltage of a P-channel transistor.

7. The method of claim 6, wherein the magnitude of the negative voltage of a P-channel transistor is increased from about 0.5 to 0.6 when the DPN treatment time is increased from about 60 seconds to 90 seconds.

8. The method of claim 1, further comprising doping the substrate with a predetermined amount of impurities so as to further adjust the threshold voltage required to activate the device.

9. A method of inhibiting mobility of charge carriers in an isolation layer of a semiconductor device, the method comprises:
forming the isolation layer in a semiconductor substrate;
incorporating nitrogen into the isolation layer.

10. The method of claim 9, wherein incorporating nitrogen into the isolation layer comprises depositing between about 10 to 25% of nitrogen within the isolation layer.

11. The method of claim 9, wherein incorporating nitrogen into the isolation layer comprises providing the isolation layer with a concentration of nitrogen that is between about 10 to 25%.

12. The method of claim 9, wherein forming the isolation layer comprises forming an oxide layer.

13. The method of claim 12, wherein nitrogen is incorporated into the oxide layer while the oxide layer is being formed.

14. The method of claim 12, wherein incorporating nitrogen into the isolation layer comprises exposing the oxide layer to an energetic nitrogen environment and forming a layer of nitride on the upper surface of the gate oxide.

15. The method of claim 12, wherein nitrogen is incorporated into the oxide layer and corrects structural defects present in the oxide layer, wherein the structural defects comprises atomic vacancies present in the oxide layer.

16. The method of claim 15, wherein the nitrogen atoms fill the atomic vacancies present in the oxide structure and substantially reduce the charge that has developed in the oxide layer as a result of these atomic vacancies.

17. The method of claim 9, wherein incorporating nitrogen into the isolation layer comprising utilizing a decoupled plasma nitridization process and a doping process.

18. The method of claim 12, wherein the oxide layer comprises BST.

19. A semiconductor device, comprising:
a semiconductor substrate;
an isolation layer formed on a first surface of the semiconductor substrate, wherein nitrogen is incorporated into the isolation layer to inhibit mobility of charge carriers in the isolation layer;
a gate structure formed on a first surface of the isolation layer, wherein application of a threshold voltage to the gate results in the creation of a depletion region in the region of the semiconductor substrate located adjacent the isolation layer.

20. The semiconductor device of claim 19, wherein the device has a threshold voltage of between about 0.1 to 3 volts.

21. The semiconductor device of claim 19, wherein the semiconductor device comprises a transistor.

22. The semiconductor device of claim 19, wherein the semiconductor device comprises a dual-gate transistor.

23. The semiconductor device of claim 19, the isolation layer has an N-gradient concentration.

24. The semiconductor device of claim 19, wherein the transistor mobility is improved by about 25% as compared to the transistor mobility of device formed without incorporating nitrogen into the isolation layer.

25. The semiconductor device of claim 19, wherein the dielectric of the isolation layer is higher when compared to an equivalent isolation layer without nitrogen incorporation.
